(19) United States
(12) Patent Application Publication
(10) Pub. No.: US 2025/0178216 A1
(43) Pub. Date: Jun. 5, 2025

(54) WORKPIECE MANUFACTURING DEVICE AND WORKPIECE MANUFACTURING METHOD

(71) Applicant: NHK SPRING CO., LTD., Yokohama-shi (JP)

(72) Inventor: Kenichiro NAKANO, Yokohama-shi (JP)

(73) Assignee: NHK SPRING CO., LTD., Yokohama-shi (JP)

(21) Appl. No.: 18/966,280

(22) Filed: Dec. 3, 2024

(30) Foreign Application Priority Data
Dec. 5, 2023 (JP) 2023-205048

(51) Int. Cl. B25J 15/06

(52) U.S. Cl. CPC B25J 15/0616

(57) ABSTRACT

A workpiece manufacturing device includes a cylinder mechanism, an electro-pneumatic regulator, a load sensor, an image capturing device. The cylinder mechanism is operated by driving gas. A piezoelectric element as an example of the fragile component, is sucked by a sucking portion and then is arranged on a piezo mounting portion. Information on the pressure of the driving gas at the time of the arrangement of the piezoelectric element is input to the recording unit. The pressing load at the time of the arrangement of the piezoelectric element is input to the recording unit. An image of the piezoelectric elements is captured by the image capturing device, and information (for example, on presence or absence of cracks) on the image is recorded in the recording unit.

### CROSS-REFERENCE TO RELATED APPLICATIONS

This application is based upon and claims the benefit of priority from prior Japanese Patent Application No. 2023-205048, filed Dec. 5, 2023, the entire contents of which are incorporated herein by reference.

### BACKGROUND OF THE INVENTION

### 1. Field of the Invention

The present invention relates to a manufacturing method of a workpiece including fragile components such as piezoelectric element and a manufacturing device of the workpiece.

### 2. Description of the Related Art

A disk drive is used in an information processing apparatus such as a personal computer. The disk drive includes a magnetic disk rotatable about a spindle, a carriage pivotable about a pivot, and the like. A disk drive suspension is provided on an arm of the carriage. In the specification, the disk drive suspension may also be simply referred to as a suspension.

The disk drive suspension comprises a baseplate, a load beam, a flexure arranged along the load beam and the like. A slider is provided on a gimbal portion formed near a distal end of the flexure. The slider is provided with elements for accessing data, that is, for reading or writing data stored in a disk.

In order to handle the increase in the recording density of disks, the magnetic head has to be more precisely positioned relative to the recording surface of each disk. JP 2002-50140 A (Patent Literature 1) and JP 2011-216160 A (Patent Literature 2) disclose examples of the suspensions. These suspensions include piezoelectric elements functioning as actuators. Piezoelectric elements are hereinafter referred to as “piezo” as well. The disk drive suspension is an example of the workpiece. The piezoelectric element is an example of a fragile component.

The piezoelectric elements (piezo) used for the workpiece are arranged on a component mounting portion of a workpiece. Before fixing these piezoelectric elements to the component mounting portion, adhesive is applied to the component mounting portion. The piezoelectric elements are arranged on this adhesive. The adhesive cures to fix the piezoelectric elements to the component mounting portion.

In order to arrange small electric parts on the workpiece, for example, a component mounting device comprising a sucking nozzle can be used. For example, JP 2006-286781 A (Patent Literature 3) discloses a component mounting device comprising a sucking nozzle. Piezoelectric elements are thin, for example, from several tens of micrometers to several hundreds of micrometers and are significantly fragile. Therefore, crack may be formed in the piezoelectric element due to application of only slight amount of external force.

The workpieces such as suspensions, which have been completed after the series of manufacturing processes, are inspected in an inspection process in the end to determine presence or absence of any abnormalities. Various electronic components are arranged on the completed workpieces. In the inspection process, the electrical characteristics and various items of the workpiece are inspected. If any abnormalities are found in the completed workpiece, the manufacturing process of the workpieces is traced to find the cause of the abnormalities. When the cause is found in the manufacturing process, measures are taken to resolve the problem.

Workpieces such as a suspension are manufactured through a various processes. In addition, large quantities of workpieces are manufactured. Therefore, it is difficult to identify which manufacturing process resulted in defective workpieces. The inventors of the present invention conducted profound research and found a considerable number of cases where cracks are formed in fragile components such as piezoelectric elements.

The piezoelectric elements that have cracks involve abnormal electrical characteristics and thus can be found by electrical inspection. However, even when the defective products are found in the inspection of the completed workpieces, a large number of workpieces have already been manufactured by the time of inspection. Therefore, a large number of defective products may be manufactured.

In light of this situation, it is necessary to guarantee that fragile components such as piezoelectric elements are not damaged at a relatively early stage in the manufacturing processes of the workpieces. In addition, in order to minimize the number of defective products, it is important to detect the presence or absence of damages in fragile components at a relatively early stage of the manufacturing processes. In addition, it is beneficial to take countermeasures immediately when damages are found in the workpieces.

The present invention aims to provide a manufacturing device of a workpiece and manufacturing method of the workpiece that are capable of suppressing the occurrence of defective products in the process of mounting fragile components on the workpieces and capable of being used as a basis for guaranteeing the soundness of the fragile components.

### BRIEF SUMMARY OF THE INVENTION

One embodiment is a workpiece manufacturing device comprising a component mounting portion on which a fragile component is mounted and including a cylinder mechanism, an electro-pneumatic regulator, a sucking portion, a load sensor, an image capturing device, an image inspection portion, and a recording unit. The cylinder mechanism is operated by driving gas such as air. The electro-pneumatic regulator supplies the driving gas to the cylinder mechanism. The sucking portion is provided in the cylinder mechanism and sucks the fragile component.

The load sensor detects a pressing load applied to the fragile component when the sucking portion presses the piezoelectric element. The image capturing device captures an image of the fragile component arranged on the component mounting portion. The image inspection unit processes the image of the fragile component captured by the image capturing device. The recording unit records information on the driving gas when the sucking portion presses the fragile component. Further, the recording unit records information on the pressing load and information on the image processed by the image inspection unit. An example of the workpiece is a disk drive suspension. A piezoelectric elements is an example of the fragile component. A piezo mounting portion is an example of the component mounting portion.

According to the present invention, the presence or absence of damages in a fragile component at the time of arrangement of the fragile component on the component mounting portion of the workpiece can be detected. It is also possible to manage information such as the pressure of the driving gas and the pressing load applied to the fragile component when the fragile component is arranged. This is effective in guaranteeing the soundness of the fragile component.

In the manufacturing device of the present embodiment, information on whether or not a crack has been formed in the fragile component may be recorded in the recording unit. The device may also include a display unit displaying the information recorded in the recording unit.

An embodiment of a manufacturing method of the workpiece comprises sucking the fragile component to a sucking portion. The sucked fragile component is arranged on the component mounting portion by a cylinder mechanism operated by driving gas from an electro-pneumatic regulator. Information on the driving gas at the time of the sucking portion pressing the fragile component is recorded in a recording unit. The pressing load applied to the fragile component is detected. The information on the pressing load is recorded in the recording unit. An image of the fragile component arranged on the component mounting portion is captured by an image capturing device. Information on this captured image is recorded in the recording unit.

In the manufacturing method of the present embodiment, the pressing load may be fed back to the electro-pneumatic regulator, and the cylinder mechanism may be controlled such that the pressing load falls within a predetermined range. Cracks may be formed in the fragile component whose image has been captured by the image capturing device. When a crack is found in the fragile component, the pressing load may be fed back to the electro-pneumatic regulator, and the pressure of the driving gas may be adjusted to a value at which no cracks occur. Absence of cracks at the time of mounting the fragile component may be guaranteed based on the information recorded in the recording unit.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is a perspective view schematically showing a part of a workpiece manufacturing device (piezo mounting device) of one embodiment.

FIG. 2 is a plan view showing a suspension as an example of a workpiece.

FIG. 3 is a perspective view schematically showing a part of the workpiece manufacturing device shown in FIG. 1 and a piezoelectric element assembly.

FIG. 4 is a perspective view schematically showing a state where a sucking portion of the workpiece manufacturing device shown in FIG. 3 sucks piezoelectric elements.

FIG. 5 is a cross-sectional view showing a sucking portion of the workpiece manufacturing device shown in FIG. 1 and a part of a workpiece.

FIG. 6 is a flowchart showing a part of the manufacturing processes of the suspension.

### DETAILED DESCRIPTION OF THE INVENTION

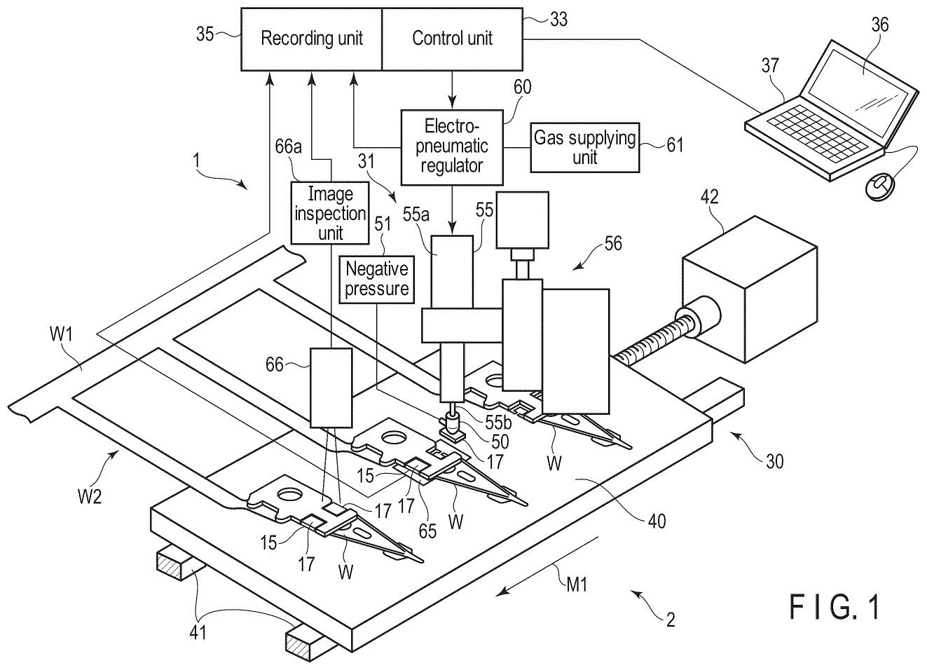

A workpiece manufacturing device and a manufacturing method of a workpiece will be described with reference to FIG. 1 to FIG. 6.

FIG. 1 is a perspective view schematically illustrating a piezo mounting device 1, which constitutes a part of the workpiece manufacturing device. The piezo mounting device 1 is arranged on a piezo mounting stage 2. The piezo mounting stage 2 is a part of the equipment for manufacturing suspensions.

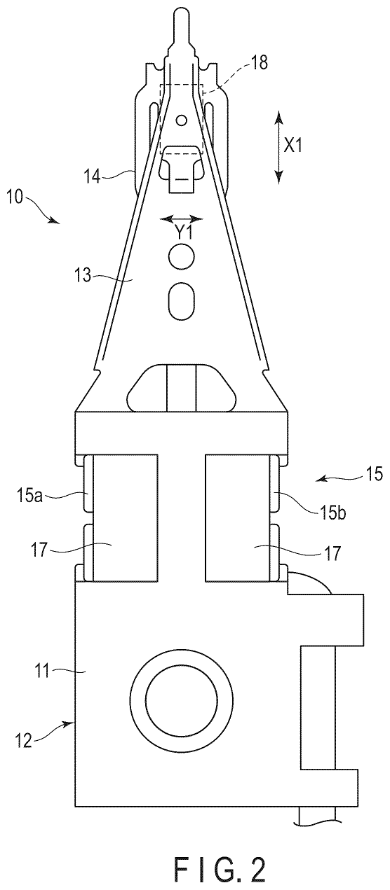

FIG. 2 shows an example of a workpiece to be manufactured (disk drive suspension 10). Hereinafter, the disk drive suspension 10 will simply be referred to as a suspension 10. The suspension 10 shown in FIG. 2 comprises a base portion 12, a load beam 13, a flexure 14, and a piezo mounting portion 15. The base portion 12 includes a base plate 11. The load beam 13 is made of stainless steel plate. The piezo mounting portion 15 is an example of the component mounting portion. The piezo mounting portion 15 includes a first mounting portion 15a and a second mounting portion 15b. A piezoelectric element 17, which is a fragile component, is arranged on each of these mounting portions 15a and 15b. In the present specification, the term “piezoelectric element” is referred to as “piezo” in some cases. Fragile components may be other than piezoelectric elements.

For the sake of explanations, the direction indicated by X1 in FIG. 2 is referred to as the length direction of the suspension 10, and the direction indicated by Y1 is referred to as the width direction. The flexure 14 extends along the load beam 13 in the length direction of the suspension 10. A gimbal portion is formed near a distal end of the flexure 14. A slider 18, which functions as a magnetic head, is arranged on the gimbal portion.

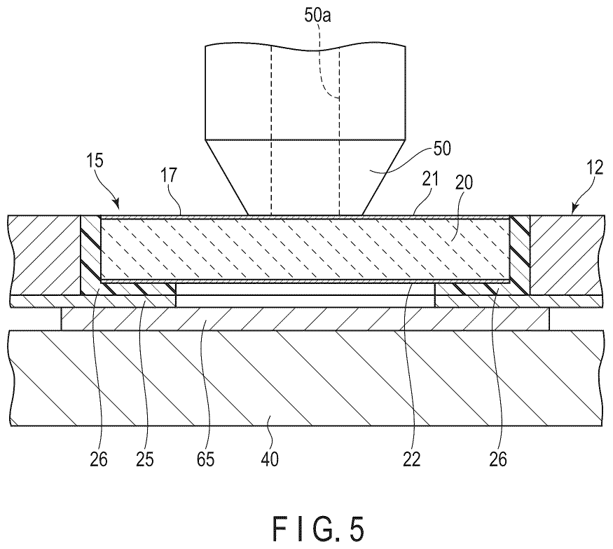

FIG. 5 shows an example of the piezo mounting portion 15. Piezoelectric elements 17 are arranged on the piezo mounting portion 15. The piezoelectric element 17 comprises a piezoelectric body 20, a first electrode 21, and a second electrode 22. The piezoelectric body 20 is made of piezoelectric material. The first electrode 21 is provided on one face of the piezoelectric body 20. The second electrode 22 is provided on the other face of the piezoelectric body 20. The piezoelectric body 20 is formed of piezoelectric materials having both piezoelectric effect and inverse piezoelectric effect. The example of the piezoelectric material is zirconate titanate (PTZ).

As shown in FIG. 5, the piezoelectric element 17 is fixed to a support portion 25 of the piezo mounting portion 15 by means of an insulating adhesive 26. The piezoelectric element 17 has the function of moving the tip portion of the suspension 10 in the width direction by a small amount. When a voltage is applied to the piezoelectric element 20, the piezoelectric element 20 expands or contracts in response to the voltage, and thus the tip portion of the suspension 10 moves.

The piezo mounting device 1 shown in FIG. 1 has the function for mounting the piezoelectric element 17 on the piezo mounting portion 15 of the suspension 10. In the present specification, workpieces in the middle of manufacturing, in other words, workpieces before the completion of the manufacturing of the suspension 10, are referred to as an intermediate product W. The piezo mounting device 1 is arranged on the piezo mounting stage 2.

As shown in FIG. 1, the piezo mounting device 1 includes a conveyance mechanism 30, a piezo supplying mechanism 31, a control unit 33, a recording unit 35, a display unit 36, and the like. The conveyance mechanism 30 conveys the workpiece. The piezo supplying mechanism 31 supplies the piezoelectric elements 17 to the piezo mounting portion 15. The recording unit 35 includes a memory to store data. The control unit 33, the recording unit 35, the display unit 36, and the like may be included in an information processing device 37 such as a personal computer. The recording unit 35 may be a database other than the information processing device 37.

The conveyance mechanism 30 includes a workpiece support body 40 and a drive unit 42. A plurality of intermediate products W are arranged on the workpiece support body 40. The drive unit 42 moves the workpiece support body 40 along a guide member 41. The plurality of intermediate products W are connected to each other by a frame W1 to form a chain sheet W2. The chain sheet W2 is arranged on the workpiece support body 40. The drive unit 42 conveys the chain sheet W2 along the direction indicated by the arrow M1 in FIG. 1.

The piezo supplying mechanism 31 includes a sucking portion 50 and a negative pressure source 51, which generates negative pressure for the sucking portion 50. The sucking portion 50 includes an inlet 50a (shown in FIG. 5). By sucking air through the inlet 50a, the piezoelectric element 17 is sucked to the sucking portion 50. Furthermore, the piezo supplying mechanism 31 includes a cylinder mechanism 55, a movement mechanism 56, which moves the cylinder mechanism 55, and an electro-pneumatic regulator 60. The cylinder mechanism 55 moves the sucking portion 50 mainly in the vertical direction.

A gas supply source 61 is connected to the electro-pneumatic regulator 60. The gas supply source 61 supplies pressurized gas (for example, air) to the electro-pneumatic regulator 60. The electro-pneumatic regulator 60 controls the pressure of the gas supplied from the gas supply source 61 and supplies this gas to the cylinder mechanism 55. In the specification, the gas whose pressure has been controlled may also be referred to as driving gas. In general, the driving gas is air. However, other gases such as chemically inert gases may be used.

An example of the electro-pneumatic regulator 60 includes an intake solenoid valve, which is electrically controlled by the control unit 33. The electro-pneumatic regulator 60 further includes an exhaust solenoid valve, a pressure sensor, and the like. When the piezoelectric element 17 is placed on the piezo mounting portion 15, information on the pressure of the driving gas is monitored by the pressure sensor. Information on the pressure of the driving gas is recorded in the recording unit 35.

The cylinder mechanism 55 includes a cylinder main body 55a and a rod portion 55b. The driving gas is supplied to the cylinder main body 55a. The rod portion 55b extends downward from the cylinder main body 55a. The rod portion 55b operates in response to the pressure of the driving gas supplied to the cylinder main body 55a. The sucking portion 50 moves in vertical direction according to the cylinder mechanism 55, which is operated by the driving gas.

When the piezoelectric element 17 is placed on the piezo mounting portion 15, the electro-pneumatic regulator 60 supplies the driving gas to the cylinder mechanism 55. Thus, the piezoelectric element 17 is pressed by the pressure of the driving gas towards the support portion 25 of the piezo mounting portion 15 by a small load (pressing load). An example of the cylinder mechanism 55 is an air static pressure air cylinder that can control small pressing loads. The piezoelectric element 17 arranged on the piezo mounting portion 15 is pressed by a minute load by the sucking portion 50, which operates in response to the driving gas.

As shown in FIGS. 1 and 5, a load sensor 65 such as a load cell is provided on the workpiece support body 40. The load sensor 65 may also be provided in the cylinder mechanism 55.

The piezoelectric element 17 arranged on the piezo mounting portion 15 is pressed by the sucking portion 50. At this time, the load sensor 65 detects the load (pressing load) applied to the piezoelectric element 17. Information on this pressing load is stored in the recording unit 35. Preferably, the pressing load detected by the load sensor 65 is fed back to the electro-pneumatic regulator 60. The sucking portion 50 can press the piezoelectric element 17 within a predetermined scope of pressing loads by controlling the cylinder mechanism 55 based on the pressing load, which has been fed back.

As shown in FIG. 1, an image capturing device 66 is arranged on the piezo mounting stage 2. The image capturing device 66 is arranged on the downstream side of the movement direction of the workpiece with respect to the piezo supplying mechanism 31. An example of the image capturing device 66 is a camera using a solid-state image capturing device (CCD). The image capturing device 66 captures an image of the piezoelectric element 17 arranged on the piezo mounting portion 15. The image captured by the image capturing device 66 is processed in an image inspection unit 66a.

The image inspection unit 66a processes the image of the piezoelectric element 17 based on a predetermined algorithm. Information on this processing captured image is output to the recording unit 35. For example, information such as whether or not the piezoelectric element 17 has damages such as cracks is recorded in the recording unit 35. The information recorded in the recording unit 35 may be displayed on the display unit 36. In cases where damages such as cracks are detected, the pressing load at the time of mounting the piezoelectric element 17 may be fed back to the electro-pneumatic regulator 60. Measures such as reducing the pressure of the driving gas may be taken based on the pressing load, which has been fed back.

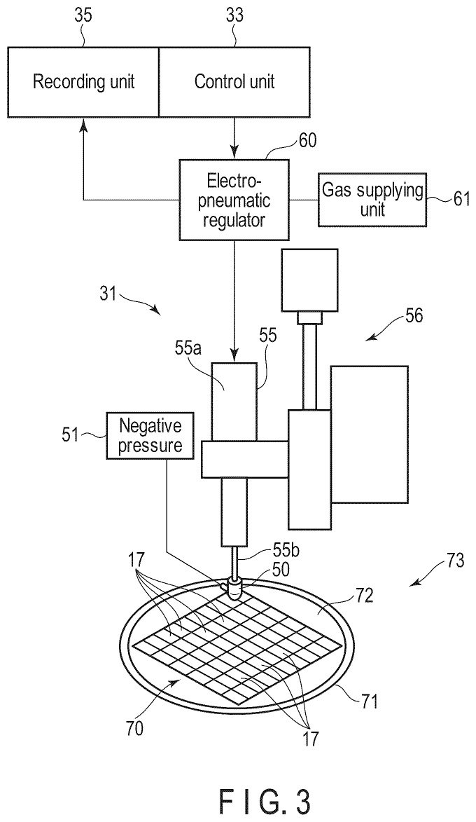

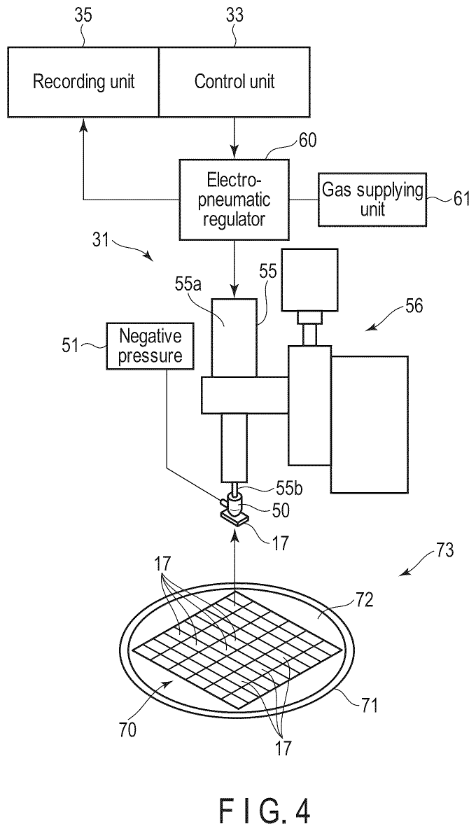

FIG. 3 and FIG. 4 show a piezo assembly 70. The piezo assembly 70 is constituted by the plurality of piezoelectric elements 17 before being mounted on the intermediate product W. A sheet member 72 is provided inside a ring frame 71, for example. The piezoelectric assembly 70 is arranged on this sheet member 72. The ring frame 71, the sheet member 72, and the piezo assembly 70 are provided on a piezo standby stage 73.

As shown in FIG. 3, the sucking portion 50 descends toward the piezo assembly 70. The sucking portion 50 having descended approaches a specific piezoelectric element 17, which is to be sucked, and then stops. At this time, air is sucked in through the inlet 50a of the sucking portion 50. In this state, the piezoelectric element 17 to be sucked is raised by a small amount by a pushing-up member from the lower side of the sheet member 72. In this manner, the target piezoelectric element 17 is sucked by the sucking portion 50.

As shown in FIG. 4, the cylinder mechanism 55 rises in a state where the piezoelectric elements 17 is sucked by the sucking portion 50. This makes the sucking portion 50 and the piezoelectric element 17 rise. Thereafter, as shown in FIG. 1, the sucking portion 50 and the piezoelectric element 17 are moved directly above the piezo mounting portion 15. Then, the driving gas supplied from the electro-pneumatic regulator 60 causes the sucking portion 50 to move downward. Thus, the piezoelectric element 17 is arranged on the piezo mounting portion 15.

Before the piezoelectric element 17 is arranged on the piezoelectric mounting portion 15, uncured liquid adhesive 26 (shown in FIG. 5) is applied to the piezo mounting portion 15. The piezoelectric element 17 sucked by the sucking portion 50 is arranged on the uncured adhesive 26. Thereafter, the sucking portion 50 is moved slightly downward by the driving gas supplied from the electro-pneumatic regulator 60 to the cylinder mechanism 55. Thus, the piezoelectric element 17 is pressed toward the uncured adhesive 26. At this time, the piezoelectric element 17 is sucked to the sucking portion 50. Therefore, the piezoelectric elements 17 is prevented from moving in random directions on the uncured adhesive 26.

The pressure of the driving gas supplied through the electro-pneumatic regulator 60 to the cylinder mechanism 55 is constantly monitored. For example, information on the driving gas at the time of the piezoelectric element 17 being pressed by the sucking portion 50 in a state where the piezoelectric element 17 is arranged on the piezo mounting portion 15 is recorded in the recording unit 35. In addition, the load sensor 65 detects the pressing load applied to the piezoelectric element 17 at the time of the sucking portion 50 pressing the piezoelectric element 17. Information on this pressing load is recorded in the recording unit 35.

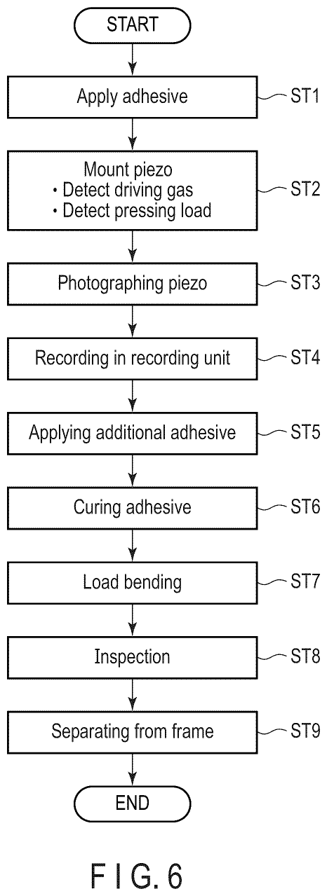

FIG. 6 is a flowchart showing a part of the manufacturing processes of the suspension. A series of processes ST1 to ST8 described below are conducted in a state where a plurality of intermediate products W are connected to the frame W1 (in the state of the chain sheet W2 shown in FIG. 1).

In the adhesive application process ST1 shown in FIG. 6, the uncured adhesive 26 (shown in FIG. 5) is applied to the piezo mounting portion 15. The adhesive 26 is applied to the piezo mounting portion 15 by a dispenser.

In the process ST2 of mounting the piezoelectric element, the piezoelectric element 17 is arranged on the piezo mounting portion 15. For example, as shown in FIG. 3, the sucking portion 50 descends toward the piezo assembly 70, and the piezoelectric element 17 is sucked by the sucking portion 50. As shown in FIG. 4, the piezoelectric element 17 sucked to the sucking portion 50 rises. Thereafter, as shown in FIG. 1, the piezoelectric element 17 sucked to the sucking portion 50 is moved directly above the piezo mounting portion 15.

As shown in FIG. 5, the piezoelectric element 17 is arranged on the uncured adhesive 26. In this state, the driving gas is supplied from the electro-pneumatic regulator 60 to the cylinder mechanism 55. This causes the piezoelectric element 17 to be pushed slightly by the sucking portion 50. Information on the pressure of the driving gas at this time is recorded in the recording unit 35. In addition, the pressing load at the time of the piezoelectric element 17 being pressed is detected by the load sensor 65. This detected information of the pressing load is recorded in the recording unit 35. After the piezoelectric element 17 is arranged on the piezo mounting portion 15, the negative pressure of the sucking portion 50 is released. Then the sucking portion 50 rises.

In the image capturing process (ST3) shown in FIG. 6, the image of the piezoelectric element 17 arranged on the piezo mounting portion 15 is captured by the image capturing device 66. The captured image is analyzed by the image inspection unit 66a. Based on the analyzed image, whether the piezoelectric elements 17 have damages such as cracks, and other inspection items are determined. In the process ST4 shown in FIG. 6, the result of the image processing is recorded. In other words, in the process ST4, the result of the image processing is recorded in the recording unit 35. The cause of the cracks can be specified to a certain extent by analyzing the degree of the cracks and the position of the cracks, and the like. For example, cases in which the pressing load of the cylinder mechanism 55 has problems can be determined. Alternatively, cases in which the relative position of the piezoelectric element 17 and the sucking portion 50 is poor, and the like can be determined.

In the process ST5, additional adhesive is applied. In the process ST5, additional adhesive is applied to the surrounding area of the piezoelectric element 17 and the like as necessary. ST6 is a process for curing the adhesive. In the process ST6, the adhesive is cured. In the process ST6, the adhesive 26 is cured. When the adhesive 26 is a thermosetting type, the adhesive is heated to be cured in a high-temperature atmosphere. When the adhesive is a UV-setting type, UV light is applied to the adhesive. The adhesive is cured due to the applied UV light.

In the process ST7, the suspension 10 is bent. In the process ST7, a portion in the vicinity of the base portion 12 of the suspension 10 is bent in the thickness direction. So-called load bending is performed in the process ST7. By this load bending in the process ST7, the degree of bending of the suspension 10 with respect to a disk and the spring load can be optimized.

In the inspection process ST8 shown in FIG. 6, the suspension 10 is inspected. In this inspection process ST8, for example, the electrical characteristics of the suspension 10 and the shape of the suspension 10 are closely inspected. In the inspection process ST8, damages such as cracks in the piezoelectric element 17 can be detected by measuring the electrical characteristics of the piezoelectric element 17.

The completed suspension 10 is manufactured through many manufacturing processes. Therefore, even if damages in the piezoelectric element 17 are detected in the inspection process ST8, many suspensions 10 have been manufactured at the time of this detection. Furthermore, tracing back the manufacturing process to identify the cause of the damage requires considerable effort. Even if measures are taken after the detection of the damages in the piezoelectric element, many defective products may have already been produced at the time of this detection.

In contrast, the workpiece manufacturing device and the manufacturing method of the workpiece of the present embodiment, the status of the piezoelectric element immediately after being arranged on the piezo mounting portion is recorded in the recording unit 35. Therefore, damages in the arranged piezoelectric element can be found at early stage of the manufacturing processes of the suspension. The driving gas supplied from the electro-pneumatic regulator 60 is monitored. It can be confirmed that the driving gas pressure does not exceed the predetermined range. In addition, it can be proved that the pressure setting of the driving gas has no problems.

The cylinder mechanism 55 and the electro-pneumatic regulator 60 may have problems. The present embodiment can analyze these problems based on the information recorded in the recording unit 35. Furthermore, the information stored in the recording unit 35 can guarantee the normality of the operation of the piezoelectric element 17 at the time of the arrangement of the piezoelectric elements 17 on the piezo mount portion.

In the inspection process ST8 in FIG. 6, the suspension 10 that has been judged to be acceptable is sent to the process ST9 of separating the frame. In the process ST9, the suspension 10 is separated from the frame W2 (shown in FIG. 1) and becomes an individual product.

Needless to say, when carrying out the present invention, the specific forms of each of the elements constituting the workpiece manufacturing device may be modified variously, such as the fragile component as the workpiece, the component mounting portion, and the like. The technical concept of the present invention can be applied to workpieces other than the suspension and to workpieces comprising fragile components other than piezoelectric elements.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing device of a workpiece comprising a component mounting portion on which a fragile component is arranged, the manufacturing device comprising:
a cylinder mechanism operated by a driving gas;
an electro-pneumatic regulator supplying the driving gas to the cylinder mechanism;
a sucking portion arranged on the cylinder mechanism and sucking the fragile component;
a load sensor detecting a pressing load applied to the fragile component when the fragile component is pressed by the sucking portion;
an image capturing device capturing an image of the fragile component arranged on the component mounting portion;
an image inspection unit processing the image of the fragile component captured by the image capturing device; and
a recording unit recording information on a pressure of the driving gas when the fragile component is pressed by the sucking portion, information on the pressing load, and information on the image processed by the inspection unit.

2. The manufacturing device of claim 1, wherein
information on whether a crack is formed in the fragile component is recorded in the recording unit.

3. The manufacturing device of claim 1, further comprising:
a display unit displaying the information recorded in the recording unit.

4. A manufacturing method of a workpiece comprising a component mounting portion on which a fragile component is arranged, the method comprising:
sucking the fragile component to a sucking portion;
arranging the sucked fragile component on the component mounting portion by a cylinder mechanism operated by driving gas from an electro-pneumatic regulator;
recording information on the driving gas when the sucking portion presses the fragile component arranged on the component mounting portion in the recording unit;
detecting a pressing load applied to the fragile component;
recording information on the pressing load in the recording unit;
capturing an image of the fragile component arranged on the component mounting portion by an image capturing device; and
recording information on the captured image in the recording unit.

5. The manufacturing method of claim 4, wherein
the pressing load is fed back to the electro-pneumatic regulator, and the cylinder mechanism is controlled such that the pressing load falls within a predetermined range.

6. The manufacturing method of claim 4, wherein
when a crack is formed in the fragile component captured by the image capturing device, a pressing load at this point is fed back to the electro-pneumatic regulator, and the pressure of the driving gas is adjusted to a value at which no cracks occur.

7. The manufacturing method of claim 4, wherein
absence of cracks at the time of mounting the fragile component is guaranteed based on the information recorded in the recording unit.

8. The manufacturing method of claim 4, wherein
the workpiece is a disk drive suspension,
the fragile component is a piezoelectric element, and
the component mounting portion is a piezoelectric mounting portion.
